(19) United States
(12) Patent Application Publication
(10) Pub. No.: US 2025/0170617 A1
(43) Pub. Date: May 29, 2025

(54) SUBSTRATE PROCESSING APPARATUS AND SUBSTRATE PROCESSING METHOD

(71) Applicant: SEMES CO., LTD., Cheonan-si (KR)

(72) Inventors: Moon Sik CHOI, Cheonan-si (KR); Min Jung KIM, Bucheon-si (KR); Sul LEE, Cheonan-si (KR)

(73) Assignee: SEMES CO., LTD., Cheonan-si (KR)

(21) Appl. No.: 18/952,012

(22) Filed: Nov. 19, 2024

(30) Foreign Application Priority Data
Nov. 23, 2023 (KR) 10-2023-0164457

(51) Int. Cl. B08B 1/52

(52) U.S. Cl. CPC B08B 1/52

(57) ABSTRACT

The apparatus includes a controller for controlling a liquid discharge unit and a support unit, in which the controller controls the support unit and the liquid discharge unit so that a substrate processing operation in which a treatment solution is supplied to the substrate to process the substrate; a substrate unloading operation in which the substrate is unloaded from the processing container after the substrate processing operation; and a container cleaning operation in which the processing container is cleaned after the substrate unloading operation are sequentially performed, and in the container cleaning operation, a primary cleaning is performed by discharging the cleaning solution from a first nozzle to the support unit, and then a secondary cleaning is performed by discharging the antistatic liquid from a second nozzle to the support unit or the processing container.

### CROSS-REFERENCE TO RELATED APPLICATIONS

This application claims priority to and the benefit of Korean Patent Application No. 10-2023-0164457 filed in the Korean Intellectual Property Office on Nov. 23, 2023, the entire contents of which are incorporated herein by reference.

### TECHNICAL FIELD

The present invention relates to a substrate processing apparatus and a substrate processing method that process a substrate.

### BACKGROUND ART

To manufacture semiconductor devices, various processes, such as photography, deposition, ashing, etching, and ion implantation, are performed. In addition, before and after these processes are performed, a cleaning process of cleaning particles remaining on the substrate is performed.

On the other hand, among the above processes, the wet etching process is processed by discharging an etching solution onto the substrate. Since the wet etching process is performed in the state where the substrate is supported on a support unit provided in a processing container, the processing container and the support unit are contaminated by the etching solution, and the processing container and the support unit are periodically cleaned with a cleaning solution.

In this case, when the support unit and the processing container are cleaned, the cleaning solution is scattered in various directions, and the scattered cleaning solution is scattered to other nozzles along with particles, causing contamination of the nozzles.

In addition, the solution used for cleaning the processing container is usually pure water, which generates static electricity when cleaning the support unit and the processing container, which affects the treatment process.

### SUMMARY OF THE INVENTION

The present invention has been made in an effort to provide a substrate processing apparatus and a substrate processing method that are capable of removing the source of contamination when other nozzles are contaminated by a cleaning solution that is scattered when a processing container is cleaned.

The present invention has also been made in an effort to provide a substrate processing apparatus and a substrate processing method that are capable of facilitates the removal of an electrostatic charge when a support unit and a processing container are cleaned.

The problem to be solved by the present invention is not limited to the above-mentioned problems, and the problems not mentioned will be clearly understood by those skilled in the art from the descriptions below.

An exemplary embodiment of the present invention provides an apparatus for processing a substrate, the apparatus including: a processing container including a processing space for processing a substrate; a support unit disposed in the processing space and for supporting the substrate; a liquid discharge unit including a treatment solution nozzle for supplying a treatment solution to the substrate supported on the support unit to process the substrate, a first nozzle for supplying a cleaning solution, and a second nozzle for supplying an antistatic liquid; and a controller for controlling the liquid discharge unit and the support unit, in which the controller controls the support unit and the liquid discharge unit so that a substrate processing operation in which the treatment solution is supplied to the substrate to process the substrate; a substrate unloading operation in which the substrate is unloaded from the processing container after the substrate processing operation; and a container cleaning operation in which the processing container is cleaned after the substrate unloading operation are sequentially performed, and in the container cleaning operation, a primary cleaning is performed by discharging the cleaning solution from the first nozzle to the support unit, and then a secondary cleaning is performed by discharging the antistatic liquid from the second nozzle to the support unit or the processing container.

According to the exemplary embodiment, the first nozzle and the second nozzle may be provided to be movable by the same arm.

According to the exemplary embodiment, the liquid discharge unit may further include a discharge head mounted on the arm, and the first nozzle and the second nozzle may be mounted on the discharge head.

According to the exemplary embodiment, the cleaning solution may be pure water, and the antistatic liquid may be carbon dioxide water.

According to the exemplary embodiment, the antistatic liquid may have specific resistivity lower than the cleaning solution.

According to the exemplary embodiment, during the primary cleaning, a top end of the processing container may be located at a position higher than a position at which the substrate is supported.

According to the exemplary embodiment, in the primary cleaning, the support unit may be rotated, and the cleaning solution sprayed to the support unit may be scattered onto an inner surface of the processing container by the rotation of the support unit.

According to the exemplary embodiment, during the secondary cleaning, a top end of the processing container may be located at a position lower than a position at which the substrate is supported.

Another exemplary embodiment of the present invention provides a method of processing a substrate, the method including: a substrate loading operation in which a substrate is loaded into a processing space provided in a processing container; a substrate processing operation in which the substrate is processed by supplying a treatment solution to the substrate while rotating a spin chuck supporting the substrate within the processing space; after the substrate processing operation, a substrate unloading operation in which the substrate is unloaded from the processing space; and after the substrate unloading operation, a container cleaning operation in which the processing container is cleaned, in which the container cleaning operation includes: a primary cleaning operation in which a cleaning solution is supplied to the spin chuck; and after the primary cleaning operation, a secondary cleaning operation in which an antistatic liquid is supplied to the spin chuck or the processing container.

According to the exemplary embodiment, the substrate processing operation may include discharging the antistatic liquid to the substrate.

According to the exemplary embodiment, the cleaning solution is supplied from a cleaning solution nozzle, and the antistatic liquid is supplied from a antistatic liquid nozzle, in which the cleaning solution nozzle and the antistatic liquid nozzle may move while being integrally coupled with a discharge head.

According to the exemplary embodiment, the cleaning solution may be pure water, and the antistatic liquid may be carbon dioxide water.

According to the exemplary embodiment, the antistatic liquid may have specific resistivity lower than the cleaning solution.

According to the exemplary embodiment, in the primary cleaning operation, a top end of the processing container may be located at a position higher than a position at which the substrate is supported.

According to the exemplary embodiment, during the primary cleaning, the cleaning solution may be scattered to an inner surface of the processing container by rotation of the spin chuck, and the processing container may be repeatedly raised and lowered.

According to the exemplary embodiment, in the secondary cleaning operation, a top end of the processing container may be located at a position lower than a position at which the substrate is supported.

According to the exemplary embodiment, the secondary cleaning operation may further include a spin chuck cleaning operation in which the antistatic liquid is discharged from a top portion of the spin chuck.

According to the exemplary embodiment, the secondary cleaning operation may further include a container top end cleaning operation in which the antistatic liquid is discharged to a top end of the processing container.

According to the exemplary embodiment, the method may further include a drying operation in which an airflow is formed around the spin chuck and the processing container by rotating the spin chuck.

Still another exemplary embodiment of the present invention provides a method of processing a substrate, the method including: transferring a substrate onto a spin chuck in a processing container; liquid-treating the substrate by supplying the substrate with a treatment solution; unloading the substrate from the processing container; and cleaning the processing container, in which the liquid-treating of the substrate includes supplying an antistatic liquid to the substrate from a discharge head mounted with a cleaning solution nozzle and an antistatic liquid nozzle, the cleaning solution nozzle supplies pure water and the antistatic liquid nozzle supplies carbon dioxide water, the cleaning of the processing container includes: a primary cleaning operation in which the spin chuck and the processing container are cleaned with the cleaning solution; and a secondary cleaning operation in which the spin chuck and the processing container are cleaned with the antistatic liquid, in the primary cleaning operation, the cleaning solution is supplied to a top surface of the rotating spin chuck in a state where a top end of the processing container is located higher than the top surface of the spin chuck, and in the secondary cleaning operation, the top end of the processing container is located lower than the top surface of the spin chuck, and the antistatic liquid is supplied from the antistatic liquid nozzle to the top surface of the spin chuck or the top end of the processing container.

The present invention has the effect of facilitating the removal of a source of contamination when another nozzle is contaminated by a cleaning solution that is scattered when cleaning a processing container.

Furthermore, the present invention has the effect of facilitating the removal of an electrostatic charge when cleaning a support unit and a processing container.

The effect of the present invention is not limited to the foregoing effects, and non-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a top plan view illustrating a substrate processing facility according to an exemplary embodiment of the present invention.

FIG. 2 is a cross-sectional view illustrating a substrate processing apparatus of FIG. 1.

FIG. 3 is a flowchart of a substrate processing method according to an exemplary embodiment of the present invention.

FIGS. 4 to 8 are process flowcharts for each operation of the substrate processing method illustrated in FIG. 3.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the apparatus in use or operation in addition to the orientation depicted in the figures. For example, if the apparatus in the figures is turned over, elements described as “below” or “beneath” other elements or features would then be oriented “above” the other elements or features. Thus, the example term “below” can encompass both an orientation of above and below. The apparatus may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be processed. However, the technical spirit of the present invention may be applied to apparatuss used for other types of substrate processing, in addition to wafers.

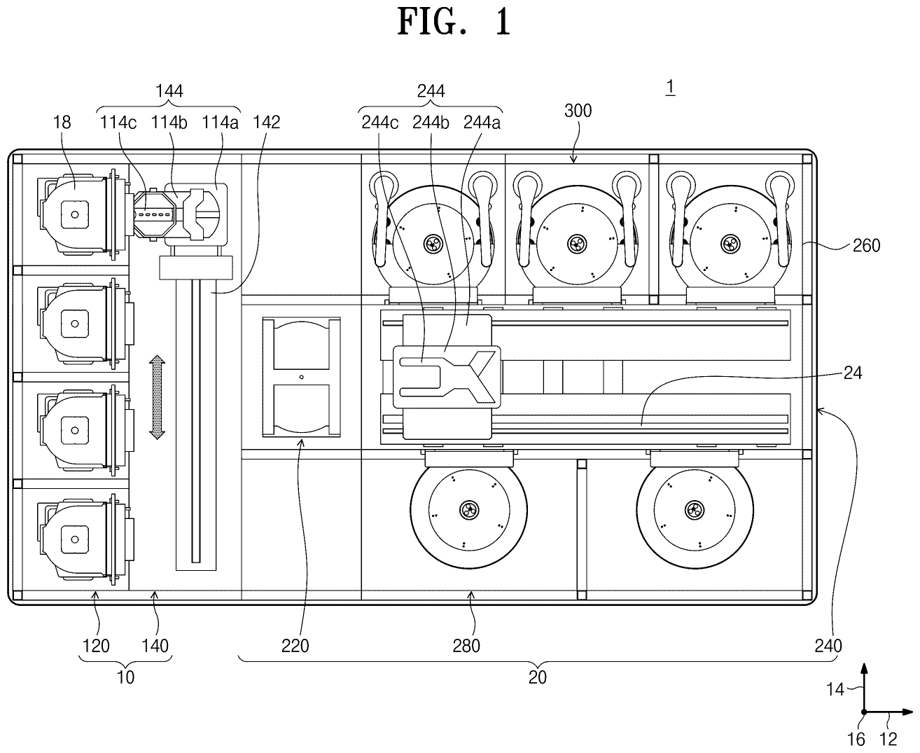

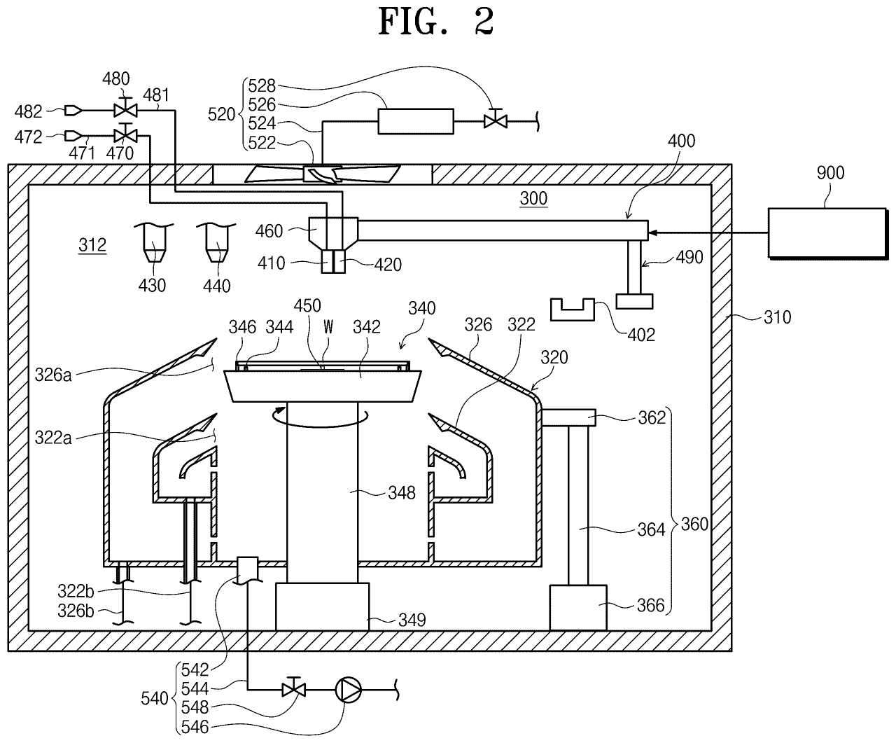

FIG. 1 is a top plan view illustrating a substrate processing facility according to an exemplary embodiment of the present invention. FIG. 2 is a cross-sectional view illustrating a substrate processing apparatus of FIG. 1.

Referring to FIGS. 1 and 2, a substrate processing facility 1 includes an index module 10 and a process processing module 20, and the index module 10 includes a load port 120 and a transfer frame 140. The load port 120, the transfer frame 140, and the process processing module 20 are arranged in sequential rows. Hereinafter, a direction in which the load port 120, the transfer frame 140, and the process processing module 20 are arranged is referred to as a first direction 12, a direction perpendicular to the first direction 12 when viewed from above is referred to as a second direction 14, and a direction perpendicular to a plane including the first direction 12 and the second direction 14 is referred to as a third direction 16.

A carrier 18 in which a substrate W is accommodated is seated on the load port 120. A plurality of load ports 120 is provided, which are arranged in a row along the second direction 14. In FIG. 1, it is illustrated that four load ports 120 are provided. However, the number of load ports 120 may be increased or decreased depending on conditions, such as process efficiency and footprint of the process processing module 20. A slot (not illustrated) provided to support an edge of the substrate W is formed in the carrier 18. The slots are provided in plural in the third direction 16, and the substrates W are stacked in the carrier while being spaced apart from each other along the third direction 16. As the carrier 18, a Front Opening Unified Pod (FOUP) may be used.

The process processing module 20 may include a buffer unit 20, a transfer chamber 240, and process chambers 260 and 280. The transfer chamber 240 is disposed so that a longitudinal direction thereof is parallel to the first direction 12. The process chambers 260 and 280 are disposed on opposite sides of the transfer chamber 240 in the second direction 14. The process chambers 260 may be provided to be symmetrical to each other relative to the transfer chamber 240. Some of the process chambers 260 and 280 are disposed along the longitudinal direction of the transfer chamber 240. Additionally, some of the process chambers 260 and 280 are arranged to be stacked on top of each other. That is, the process chambers 240 may be disposed in an array of A×B (A and B are natural numbers equal to or greater than 1) on opposite sides of the transfer chamber 240. Here, A is the number of process chambers 260 and 280 provided in a line along the first direction 12, and B is the number of process chambers 260 and 280 provided in a line along the third direction 16. When four or six process chambers 260 and 280 are provided on each of the opposite sides of the transfer chamber 240, the process chambers 260 and 280 may be disposed in an array of 2×2 or 3×2. The number of process chambers 260 and 280 may be increased or decreased. Unlike the foregoing, the process chamber 260 may be provided only to one side of the transfer chamber 240. In addition, the process chambers 260 and 280 may be provided as a single layer on one side and the opposite sides of the transfer chamber 240. In addition, the process chambers 260 and 280 may be provided in various arrangements unlike the above.

The process chambers 260 and 280 of the present exemplary embodiment may be categorized as including a cleaning chamber and a drying chamber. In this case, the cleaning chamber may be a substrate processing apparatus for cleaning the substrate W, as described hereinafter, and the drying chamber may be a substrate processing apparatus for drying the substrate W.

The buffer unit 220 is disposed between the transfer frame 140 and the transfer chamber 240. The buffer unit 220 may provide a space in which the substrate W stays before the substrate W is transferred between the transfer chamber 240 and the transfer frame 140. The buffer unit 220 is provided with slots (not illustrated) in which the substrate W is placed therein, and the slots (not illustrated) are provided in plural to be spaced apart from each other along the third direction 16. In the buffer unit 220, a side facing the transfer frame 140 and a side facing the transfer chamber 240 are each open.

The transfer frame 140 transfers the substrate W between the carrier 18 seated at the load port 120 and the buffer unit 220. The transfer frame 140 is provided with an index rail 142 and an index robot 144. The index rail 142 is provided so that a longitudinal direction thereof is parallel to the second direction 14. The index robot 144 is installed on the index rail 142, and linearly moves in the second direction 14 along the index rail 142. The index robot 144 includes a base 144a, a body 144b, and an index arm 144c. The base 144a is installed to be movable along the index rail 142. The body 144b is coupled to the base 144a. The body 144b is provided to be movable in the third direction 16 on the base 144a. Further, the body 144b is provided to be rotatable on the base 144a. The index arm 144c is coupled to the body 144b and is provided to be movable forwardly and backwardly with respect to the body 144b. A plurality of index arms 144c is provided to be individually driven. The index arms 144c are disposed to be stacked in the state of being spaced apart from each other in the third direction 16. Some of the index arms 144c may be used when the substrate W is transferred from the process processing module 20 to the carrier 18, and another some of the plurality of index arms 144c may be used when the substrate W is transferred from the carrier 130 to the process processing module 20. This may prevent the particles generated from the substrate W before the process processing from being attached to the substrate W after the process processing in the process in which the index robot 144 loads and unloads the substrate W.

The transfer chamber 240 transfers the substrate W between the buffer unit 220 and the process chambers 260. A guide rail 242 and a main robot 244 are provided to the transfer chamber 240. The guide rail 242 is disposed so that a longitudinal direction thereof is parallel to the first direction 12. The main robot 244 is installed on the guide rail 242 and linearly moved along the first direction 12 on the guide rail 242. The main robot 244 includes a base 244a, a body 244b, and a main arm 244c. The base 244a is installed to be movable along the guide rail 242. The body 244b is coupled to the base 244a. The body 244b is provided to be movable in the third direction 16 on the base 244a. Further, the body 244b is provided to be rotatable on the base 244a. The main arm 244c is coupled to the body 244b, and provided to be movable forwardly and backwardly with respect to the body 244b.

Hereinafter, a substrate processing apparatus 300 provided in the process chamber 260 will be described. The present exemplary embodiment is described based on an example in which a substrate processing apparatus 300 performs a liquid treatment process on a substrate W. The liquid treatment process further includes a process for cleaning the substrate W.

FIG. 2 is a cross-sectional view illustrating a substrate processing apparatus of FIG. 1. Referring to FIG. 2, the substrate processing apparatus 300 further includes a chamber 310, a processing container 320, a support unit 340, a lifting unit 360, a liquid discharge unit 400, an airflow formation unit 500, and a controller 900. The chamber 310 provides a processing space 312 in which a process for processing the substrate W is performed.

The processing container 320 is positioned in the processing space 312 and is provided in the shape of a cup with an open top. When viewed from above, the processing container 320 is positioned to overlap the exhaust pipe. The processing container 320 includes an internal collection container 322 and an external collection container 326. Each of the collection containers 322 and 326 collects a different treatment solution from the treatment solutions used in the process. The internal collection container 322 is provided in the shape of an annular ring surrounding the support unit 340, and the external collection container 326 is provided in the shape of an annular ring surrounding the inner collection container 322. An inner space 322a of the internal collection container 322 and a space 326a between the external collection container 326 and the internal collection container 322 function as inlets for the treatment solution to flow into the internal collection container 322 and the external collection container 326, respectively. Collection lines 322b and 326b are connected to the bottom surfaces of the collection containers 322 and 326, respectively, to extend vertically in the down direction. Each of the collection lines 322b and 326b functions as a discharge pipe to discharge the treatment solution that has been introduced through the respective collection containers 322 and 326. The discharged treatment solution may be reused through an external treatment solution regeneration system (not illustrated).

The support unit 340 may support and rotate the substrate W. The support unit 340 is disposed within the processing container 320. The substrate support unit 340 supports the substrate W and rotates the substrate W during the process progress. The support unit 340 includes a spin chuck 342, a support pin 344, a chuck pin 346, and a rotation shaft 348. The spin chuck 342 has a top surface that is substantially circular when viewed from the top. The rotation shaft 348 that is rotatable by a driver is fixedly coupled to the bottom surface of the spin chuck 342. In one example, the driver may be formed of a motor 349. A plurality of support pins 344 is provided. The support pins 344 are spaced apart on the edge portion of a top surface of the spin chuck 342 and protrude upwardly from the spin chuck 342. The support pins 344 are arranged in combination with each other to form an overall annular ring shape. The support pin 344 supports an edge of the rear surface of the substrate W so that the substrate W is spaced apart from the top surface of the spin chuck 2631 at a predetermined distance. A plurality of chuck pins 346 is provided. The chuck pins 346 are disposed to be further away from a center of the spin chuck 342 than the support pins 344. The chuck pin 346 is provided to protrude upwardly from the spin chuck 342. The chuck pin 346 supports a lateral portion of the substrate W to prevent the substrate W from laterally deviating from its stationary position when the support unit 340 is rotated. The chuck pin 346 is provided to be linearly movable between a standby position and a support position along a radial direction of the spin chuck 342. The standby position is a position further away from the center of the spin chuck 342 relative to the support position. When the substrate W is loaded into or unloaded from the support unit 340, the chuck pin 346 is positioned in the standby position, and when a process is being performed on the substrate W, the chuck pin 346 is positioned in the support position. In the support position, the chuck pin 346 is in contact with the lateral portion of the substrate W.

The lifting unit 360 regulates the relative height between the processing container 320 and the support unit 340. The lifting unit 360 linearly moves the processing container 320 in the up and down direction. As the processing container 320 is moved up and down, the relative height of the processing container 320 with respect to the support unit 340 changes. The lifting unit 460 includes a bracket 360, a moving shaft 362, and a driver 364. The bracket 362 is fixedly installed on the outer wall of the processing container 320, and a moving shaft 364, which is moved in the vertical direction by a driver 366, is fixedly coupled to the bracket 364. When the substrate W is placed on the support unit 340 or lifted from the support unit 340, the processing container 320 is lowered so that the support unit 340 protrudes above the processing container 320. Furthermore, the processing container 320 is adjusted in height so that the treatment solution flows into the respective set collection containers 322 and 326 depending on the type of treatment solution supplied to the substrate W.

Unlike the above description, the lifting unit 360 may move the support unit 340 in the upper and lower directions instead of the processing container 320.

The liquid discharge unit 400 supplies various types of liquids to the substrate W. The liquid discharge unit 400 further includes a plurality of nozzles 410 to 440. Each nozzle is moved to a process position and a standby position by a nozzle position driver 490. Here, the process position is defined as a position where the nozzles 410 to 440 are capable of discharging solutions onto the substrate W positioned within the processing container 320, and the standby position is defined as a position where the nozzles 410 to 440 are waiting outside of the process position. In one example, the process position may be a position where the nozzles 410 to 440 are capable of supplying a solution to the center of the substrate W. For example, when viewed from above, the nozzles 410 to 440 may be moved between the process position and the standby position by linear movement or axial movement. The treatment solution discharged from the liquid discharge unit 400 to the substrate W may be a treatment solution for processing the substrate W. Also, in the standby position, a collection pipe 402 may be disposed downstream of the nozzles 410 to 440. The collection pipe 402 may collect the cleaning solution when the nozzles 410 to 440 discharge the cleaning solution for cleaning.

Referring to the exemplary embodiment of FIG. 2, the liquid discharge unit 400 may include a first nozzle 410, a second nozzle 420, a treatment solution nozzle 430, a drying nozzle 440, a back nozzle 450, a discharge head 460, a first valve 470, and a second valve 480.

The first nozzle 410 may be a nozzle that discharges a first cleaning solution. The first cleaning solution may be a solution capable of cleaning chemicals remaining on the substrate W. For example, the first cleaning solution may be pure water. Further, after the substrate W is processed with the first cleaning solution, the first nozzle 410 may clean the support unit 340, the processing container 320, and the collection pipe 402. The first nozzle 410 may be connected to the first line 471 to receive a solution from a first solution supply source.

The second nozzle 420 may be a nozzle that discharges a second cleaning solution. The second cleaning solution may be an antistatic solution that removes the electrostatic charge on the substrate W when the first cleaning solution is discharged. For example, the second cleaning solution may be carbon dioxide water in which carbon dioxide is mixed with pure water. In this case, the resistivity of the antistatic solution may be formed to lower resistivity than the cleaning solution to facilitate the charge removal. Furthermore, the second nozzle 420 may be integrally coupled to the first nozzle 410 and the discharge head 460. Thus, the first nozzle 410 and the second nozzle 420 may have the same discharge position controlled by a single nozzle position driver 490. Further, the second nozzle 420 may be connected to the second line 481 to receive a solution from a second solution supply source.

The treatment solution nozzle 430 may be a nozzle that discharges a chemical. For example, the chemical may be a liquid capable of etching a film formed on the substrate W or removing particles remaining on the substrate W. The chemical may be a liquid having a property of strong acid or strong base. The chemical may include sulfuric acid, hydrofluoric acid, or ammonia. The treatment solution nozzle 430 may be variable in a discharge position by a driver (not illustrated) of the treatment solution nozzle 430 driver.

The drying nozzle 440 may be a nozzle that discharges a drying fluid. The drying fluid may be provided as a solution capable of replacing the residual rinse solution on the substrate W. The drying fluid may be a solution having lower surface tension than the rinse solution. The drying fluid may be an organic solvent. The drying fluid may be isopropyl alcohol (IPA). The drying nozzle 440 may be variable in a discharge position by a driver (not illustrated) of the drying nozzle 440.

The back nozzle 450 may be a nozzle that discharges the first cleaning solution onto the rear surface of the substrate W. The back nozzle 450 may be disposed near the center of the support unit. The rear surface of the substrate W may be cleaned by the first cleaning solution discharged from the back nozzle 450.

The discharge head 460 is schematically formed in a shape in which a coupling hole is formed in which the first nozzle 410 and the second nozzle 420 are coupled. The discharge head 460 allows the first nozzle 410 and the second nozzle 420 to be integrally coupled so that the discharge position remains constant even when the first nozzle 410 and the second nozzle 420 are moved.

The first valve 470 is installed in the first line 471. The first valve 470 may be a solenoid valve whose opening and closing operation is controlled by the controller 900. The first valve 470 may be controlled to open and close by the controller 900. The first line 471 is connected between the cleaning solution supply source 472 and the first nozzle 410 to supply a cleaning solution.

The second valve 480 is installed in the second line 481. The second valve 480 may be a solenoid valve whose opening and closing driving is controlled by the controller 900. The second valve 480 may be controlled to open and close by the controller 900. The second line 481 is connected between the antistatic solution supply source 482 and the second nozzle 420 to supply the antistatic solution. The airflow formation unit 500 forms a downward airflow in the processing space 312. The airflow formation unit 500 supplies airflow from a top portion of the chamber 310 and exhausts airflow from a lower portion of the chamber 310. The airflow formation unit 500 further includes an airflow supply unit 520 and an exhaust unit 540. The airflow supply unit 520 and the exhaust unit 540 are positioned facing each other in the vertical direction.

The airflow supply unit 520 supplies gas in the downward direction. The gas supplied from the airflow supply unit 520 may be air from which impurities are removed. The airflow supply unit 520 further includes a fan 522, an airflow supply line 524, a supply valve 528, and a filter 526. The fan 522 is installed on the ceiling surface of the chamber 310. When viewed from above, the pan 522 is positioned to face the processing container 320. The fan 522 may be positioned to provide air toward the substrate W positioned within the processing container 320. The airflow supply line 524 is connected to the fan 522 to supply air to the fan 522. A supply valve 528 is installed in the airflow supply line 524 to regulate the amount of airflow supplied. The filter 526 is installed in the airflow supply line 524 to filter the air. For example, the filter 526 may remove particles and moisture contained in the air.

The exhaust unit 540 exhausts the processing space 312. The exhaust unit 540 further includes an exhaust pipe 542, a pressure reducing member 546, and an exhaust valve 548. The exhaust pipe 542 is installed on the bottom surface of the chamber 310 and is provided as a pipe to exhaust the processing space 312. The exhaust pipe 542 is positioned such that an exhaust port faces upwardly. The exhaust pipe 542 is positioned such that the exhaust port communicates with the interior of the processing container 320. That is, the top end of the exhaust pipe 542 is positioned within the processing container 320. Accordingly, the downward airflow formed within the processing container 320 is exhausted through the exhaust pipe 542.

The pressure reducing member 546 reduces pressure of the exhaust pipe 542. The negative pressure is formed in the exhaust pipe 542 by the pressure reducing member 546, which evacuates the processing container 320. The exhaust valve 548 is installed in the exhaust pipe 542 and opens and closes the exhaust port of the exhaust pipe 542. The exhaust valve 548 regulates the exhaust volume.

The controller 900 may control the process processing module 20 with a pre-stored process algorithm to process the substrate W. In this case, the controller 900 may control the process processing module 20 to cause the substrate W to be etched by a treatment solution, cause the substrate W to be cleaned by a cleaning solution, cause the substrate W to be dried by a drying fluid, and transfer the substrate W.

In addition, the controller 900 may perform primary cleaning and secondary cleaning on the support unit and the processing container 320 with a pre-stored cleaning algorithm. In this case, the controller 900 may control the nozzle position driver 490 to set the discharge position of each of the nozzles and control the discharge drive of the nozzles by controlling the opening and closing drives for the respective valves of the nozzles. The primary cleaning of the controller 900 and the control operation regarding the primary cleaning will be described in more detail in a substrate processing method below.

Hereinafter, a substrate processing method of the substrate processing apparatus according to the exemplary embodiment of the present invention as described above will be described.

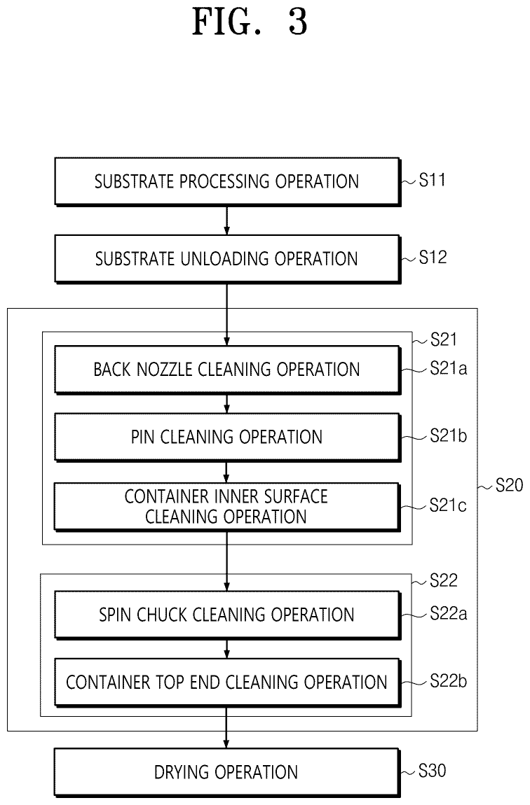

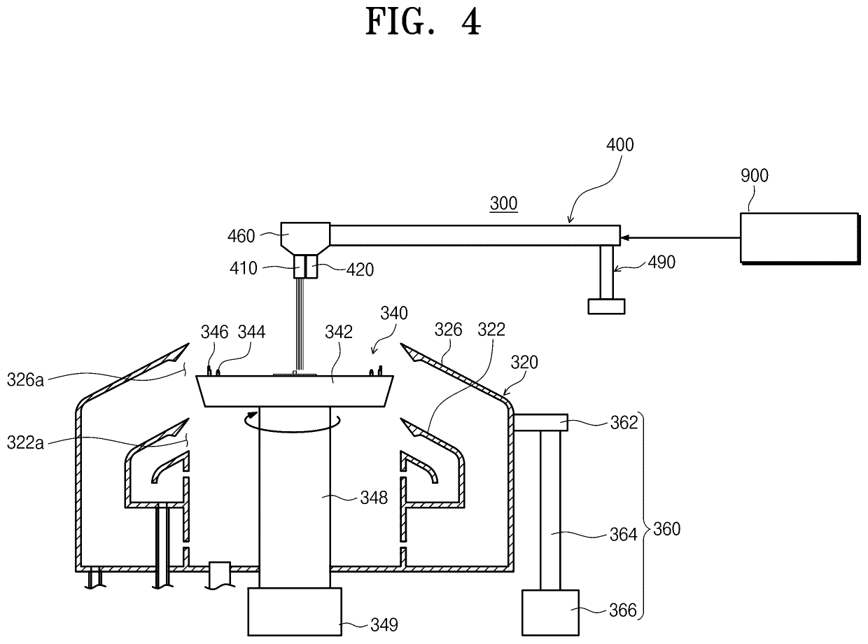

FIG. 3 is a flowchart of a substrate processing method according to an exemplary embodiment of the present invention. FIGS. 4 to 8 are process flowcharts for each operation of the substrate processing method illustrated in FIG. 3.

As illustrated in FIG. 3, a substrate processing method according to an exemplary embodiment of the present invention may include a substrate processing operation S11, a substrate unloading operation S12, a container cleaning operation S20, and a drying operation S30. Here, the substrate processing operation S11, the substrate unloading operation S12, the container cleaning operation S20, and the drying operation S30 will not be described in detail, as the controller 900 drives a substrate processing facility 1 with a preset algorithm.

In the substrate processing operation S11, the substrate W may be processed by supplying a treatment solution onto the substrate W. In this case, the substrate W may be processed by the treatment solution supplied from the treatment solution nozzle 430 while the substrate W is seated on and rotating in the spin chuck 342 of the support unit 340. Additionally, the substrate W may be supplied with a drying fluid from the drying nozzle 440 as needed for pre-drying processing. Furthermore, the substrate W may be cleaned by a cleaning solution discharged from the first nozzle 410 and an antistatic solution discharged from the second nozzle 420 after being processed by the treatment solution.

In the substrate unloading operation S12, the substrate W may be unloaded from the processing container 320 after the substrate processing operation S11. In this case, the substrate W may be transferred by the hand of the main robot 244 to another process chamber of the chamber 310 and subsequent processing may proceed.

The container cleaning operation S20 may include a primary cleaning operation S21 and a secondary cleaning operation S22. Herein, in the primary cleaning operation S21 and the secondary cleaning operation S22, the discharge position and discharge drive of the first nozzle 410 and the second nozzle 420 may be controlled by the controller 900, and the lifting and lowering drive of the processing container 320 may be controlled by the controller 900. In this case, the controller 900 may control the nozzle position driver 490 to control the discharge positions of the first nozzle 410 and the second nozzle 420, control the first valve 470 and the second valve 480 to control the discharge drive of the first nozzle 410 and the second nozzle 420, and control the lifting unit 360 to control the position of the processing container 320. In the following description, the nozzle position driver 490, the first valve 470, the second valve 480, and the lifting unit 360 are controlled by the controller 900, so the description thereof will be omitted and the description will focus on the control drive.

The primary cleaning operation S21 is an operation to clean the support unit and the processing container 320 by discharging a cleaning solution.

In one example, the primary cleaning operation S21 may include a back nozzle cleaning operation S21a, a pin cleaning operation S21b, and a container inner surface cleaning operation S21c.

The back nozzle cleaning operation S21a is an operation in which the nozzle position driver 490 is driven to move the first nozzle 410 to the top of the back nozzle 450, as illustrated in FIG. 4, and then discharge a cleaning solution from the first nozzle 410 to the back nozzle 450.

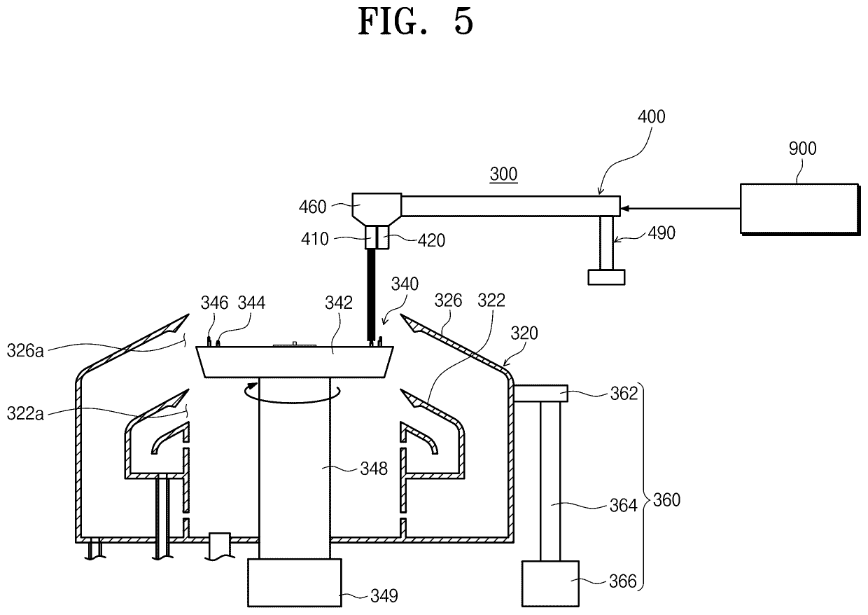

The pin cleaning operation S21b is an operation in which the nozzle position driver 490 is driven to move the first nozzle 410 to the top of the support pin 344 as illustrated in FIG. 5, and then the cleaning solution is discharged from the first nozzle 410 to the support pin 344. In the pin cleaning operation S21b, not only the support pin 344 but also the chuck pin 346 may be cleaned.

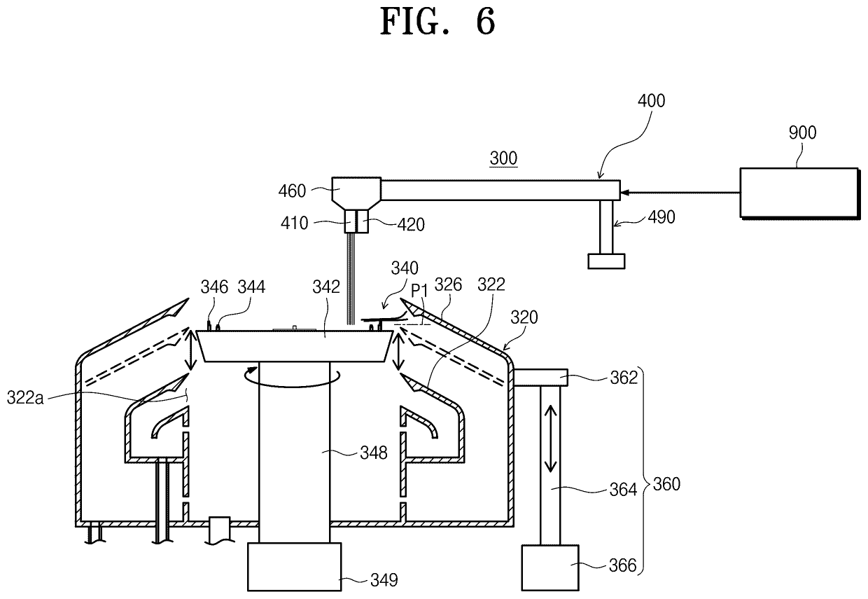

The container inner surface cleaning operation is an operation of cleaning the inner surface of the inner collection container 322 and the inner surface of the outer collection container 326 by discharging a cleaning solution from the first nozzle 410 to the top portion of the spin chuck, rotating the spin chuck 342 at a high speed, and scattering the cleaning solution on the inner surface of the inner collection container 322 and the inner surface of the outer collection container 326, as illustrated in FIG. 6. In this case, the inner collection container 322 and the outer collection container 326 may be cleaned by the cleaning solution by repeatedly performing lifting and lowering drive by the lifting unit 360. In this case, since the top end of the processing container 320 is positioned high, such as at the position PI where the substrate W is supported, the cleaning solution containing particles may not be scattered to the outside of the processing container 320.

On the other hand, when the container inner surface cleaning operation S21c is performed, the cleaning solution that is scattered on the inner surface of the inner collection container 322 and the inner surface of the outer collection container 326 may be deposited around the discharge port of the second nozzle 420 along with particles, which, if left unattended, may act as a source of contamination and cause poor processing of the substrate W when processing other substrates W subsequently. To solve this problem, the following secondary cleaning operation S22 is performed.

The secondary cleaning operation S22 is an operation in which the support unit and the processing container 320 are cleaned by using an antistatic liquid.

In one example, the secondary cleaning operation S22 may include a spin chuck cleaning operation S22a, and a container top end cleaning operation S22b.

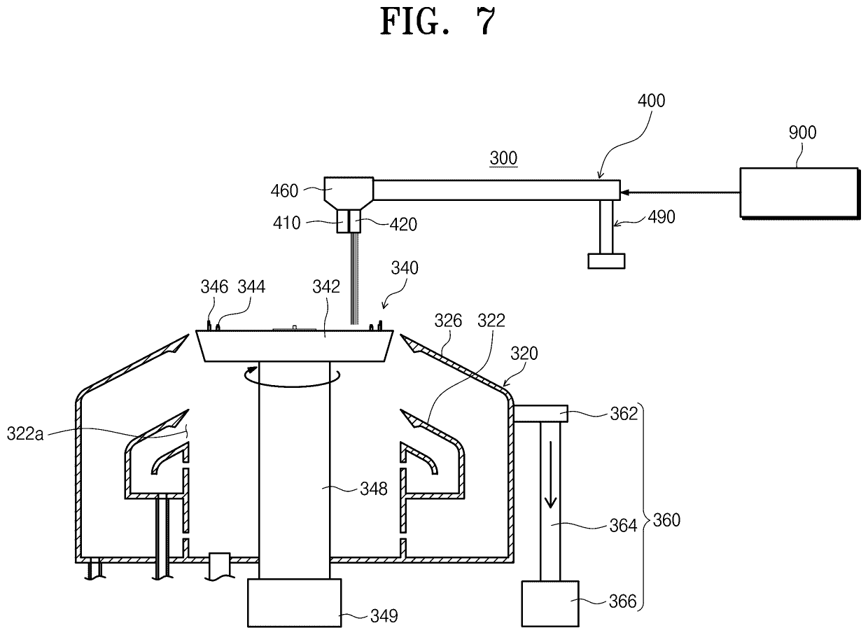

The spin chuck cleaning operation S22a is an operation in which the nozzle position driver 490 moves the second nozzle 420 to the top of the spin chuck 342, as illustrated in FIG. 7, and then an antistatic liquid is discharged from the second nozzle 420 onto the top of the spin chuck 342. In this case, the cleaning solution and particles stained in the container inner surface cleaning operation S21c are discharged by the discharge of the antistatic liquid through the second nozzle 420 and are discharged to the lower part of the spin chuck 342. Therefore, it is possible to easily remove the source of contamination formed around the second nozzle 420 during the cleaning with the cleaning solution alone. Furthermore, since the spin chuck cleaning operation S22a removes an electrostatic charge of the spin chuck 342 with the antistatic liquid, it is possible to ensure that the electrostatic force does not affect the processing of the substrate W.

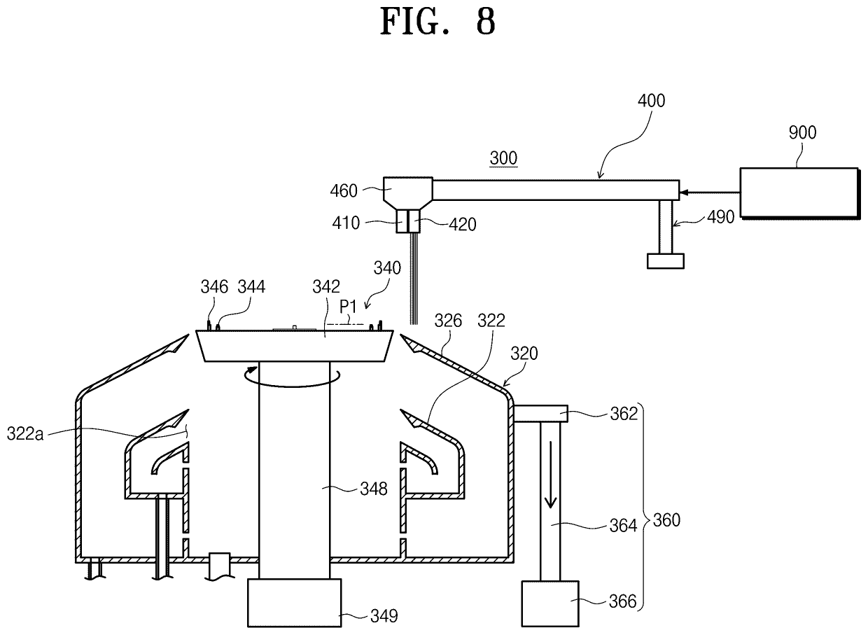

The container top end cleaning operation S22b is an operation in which the nozzle position driver 490 moves the second nozzle 420 to the top end of the processing container 320, as illustrated in FIG. 8, and then an antistatic liquid is discharged from the second nozzle 420 onto the top end of the processing container 320. The container top end cleaning operation S22b may be performed in the state where the top end of the processing container 320 is lowered to a position lower than the position P1 where the substrate W is supported. Accordingly, the antistatic liquid may be reintroduced to the spin chuck 342 side to remove the electrostatic charge formed on the processing container 320 without causing contamination.

The drying operation S30 may dry the spin chuck 342 and the processing container 320 by rotating the spin chuck 342 at a high speed to form a high-speed airflow around the spin chuck 342 and the processing container 320.

As described above, the present invention has been described with reference to the specific matters, such as a specific component, limited exemplary embodiments, and drawings, but these are provided only for helping general understanding of the present invention, and the present invention is not limited to the aforementioned exemplary embodiments, and those skilled in the art will appreciate that various changes and modifications are possible from the description.

Therefore, the spirit of the present invention should not be limited to the described exemplary embodiments, and it will be the that not only the claims to be described later, but also all modifications equivalent to the claims belong to the scope of the present invention.

1-8. (canceled)

9. A method of processing a substrate, the method comprising:
a substrate loading operation in which a substrate is loaded into a processing space provided in a processing container;
a substrate processing operation in which the substrate is processed by supplying a treatment solution to the substrate while rotating a spin chuck supporting the substrate within the processing space;
after the substrate processing operation, a substrate unloading operation in which the substrate is unloaded from the processing space; and
after the substrate unloading operation, a container cleaning operation in which the processing container is cleaned,
wherein the container cleaning operation includes:
a primary cleaning operation in which a cleaning solution is supplied to the spin chuck; and
after the primary cleaning operation, a secondary cleaning operation in which an antistatic liquid is supplied to the spin chuck or the processing container.

10. The method of claim 9, wherein the substrate processing operation includes discharging the antistatic liquid to the substrate.

11. The method of claim 9, wherein the cleaning solution is supplied from a cleaning solution nozzle, and the antistatic liquid is supplied from a antistatic liquid nozzle, wherein the cleaning solution nozzle and the antistatic liquid nozzle move while being integrally coupled with a discharge head.

12. The method of claim 9, wherein the cleaning solution is pure water, and

13. The method of claim 9, wherein the antistatic liquid has specific resistivity lower than the cleaning solution.

14. The method of claim 9, wherein in the primary cleaning operation, a top end of the processing container is located at a position higher than a position at which the substrate is supported.

15. The method of claim 9, wherein during the primary cleaning, the cleaning solution is scattered to an inner surface of the processing container by rotation of the spin chuck, and the processing container is repeatedly raised and lowered.

16. The method of claim 9, wherein in the secondary cleaning operation, a top end of the processing container is located at a position lower than a position at which the substrate is supported.

17. The method of claim 9, wherein the secondary cleaning operation further includes a spin chuck cleaning operation in which the antistatic liquid is discharged from a top portion of the spin chuck.

18. The method of claim 17, wherein the secondary cleaning operation further includes a container top end cleaning operation in which the antistatic liquid is discharged to a top end of the processing container.

19. The method of claim 9, further comprising:
a drying operation in which an airflow is formed around the spin chuck and the processing container by rotating the spin chuck.

20. A method of processing a substrate, the method comprising:
transferring a substrate onto a spin chuck in a processing container;
liquid-treating the substrate by supplying the substrate with a treatment solution;
unloading the substrate from the processing container; and
cleaning the processing container,
wherein the liquid-treating of the substrate includes supplying an antistatic liquid to the substrate from a discharge head mounted with a cleaning solution nozzle and an antistatic liquid nozzle,
the cleaning solution nozzle supplies pure water and the antistatic liquid nozzle supplies carbon dioxide water,
the cleaning of the processing container includes:
a primary cleaning operation in which the spin chuck and the processing container are cleaned with the cleaning solution; and
a secondary cleaning operation in which the spin chuck and the processing container are cleaned with the antistatic liquid,
in the primary cleaning operation, the cleaning solution is supplied to a top surface of the rotating spin chuck in a state where a top end of the processing container is located higher than the top surface of the spin chuck, and,
in the secondary cleaning operation, the top end of the processing container is located lower than the top surface of the spin chuck, and the antistatic liquid is supplied from the antistatic liquid nozzle to the top surface of the spin chuck or the top end of the processing container.
